(19) United States
(12) Patent Application Publication
(10) Pub. No.: US 2007/0081618 A1
(43) Pub. Date: Apr. 12, 2007

(54) Apparatus and method for recovering clock and data

(75) Inventor: Phil-Jae Jeon, Osan-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/523,936

(22) Filed: Sep. 20, 2006

(30) Foreign Application Priority Data
Oct. 6, 2005 (KR) 10-2005-0093696

(51) Int. Cl. H04L 7/02; H03D 3/24

(52) U.S. Cl. 375/360; 375/376

(57) ABSTRACT

An apparatus for recovering a clock and data includes a transition detecting circuit and a clock recovery circuit. The transition detecting circuit detects a transition of an input data signal to provide a transition interval of the input data signal. The clock recovery circuit generates a recovered clock based on the input data signal during the transition interval of the input data signal.

### CROSS-REFERENCE TO RELATED APPLICATION

This application claims priority under 35 USC § 119 to Korean Patent Application No. 10-2005-0093696 filed on Oct. 6, 2005, the entire contents of which are herein incorporated by reference.

### BACKGROUND OF THE INVENTION

1. Field of the Invention

The present invention relates to data communications, and more particularly to an apparatus and a method for recovering a clock and data in data communications where a reference clock is not provided.

2. Description of the Related Art

Some data interfaces transmit data and a clock for synchronization at the same time. For example, data are transmitted in form of a differential signal pair through a low voltage differential signals (LVDS) interface, which are widely used as an interface for the LCD panel. Through the LVDS interface, the clock for synchronization is transmitted along with the data.

However, other data interfaces transmit the data without the clock for synchronization. In such an interface, a clock and data recovery (CDR) apparatus receives a data signal, and recovers the clock as well as the data that are contained in the received data signal. The CDR apparatus typically has a structure similar to that of a clock generator. The interface that transmits data without clock may be configured without an additional transmission line for clock, and may reduce power consumption for clock transmission.

FIG. 1 is a block diagram illustrating a conventional CDR apparatus.

Referring to FIG. 1, the CDR apparatus 100 includes a phase detector 110, a charge pump 120, and a voltage-controlled oscillator (VCO) 130.

The phase detector 110 compares phases of a data signal DATA and a clock signal RCLK that is generated by the VCO 130, and generates a phase difference signal. The phase difference signal is provided to the charge pump 120.

The charge pump 120 increases or decreases a control voltage according to the phase difference signal. The control voltage is provided to the VCO 130.

The VCO 130 generates the clock signal RCLK in response to the control voltage. As a magnitude of the control voltage is larger, a clock signal with a higher frequency is generated. On the other hand, as the magnitude of the control voltage is smaller, a clock signal with a lower frequency is generated. The generated clock signal RCLK is fed back to the phase detector 110.

The phase difference between the clock signal RCLK and the data signal DATA may be decreased through such a feedback process, and finally the clock signal RCLK and the data signal DATA may be substantially in phase.

The conventional CDR apparatus may be configured in a simplified structure by using Hogge's phase detector, and may stably recover the data and the clock. However, the conventional CDR apparatus includes a D flip-flop, and therefore has a problem of a static skew and a limited operating speed. In addition, the conventional CDR apparatus has an unstable output frequency that is varied depending on the existence of the data transition.

### SUMMARY OF THE INVENTION

Some embodiments of the present invention provide an apparatus for recovering a clock and data, which adjusts the recovered clock during the data transition interval.

Other example embodiments of the present invention provide a method of recovering clock and data, in which a restored clock is adjusted during the data transition interval.

According to a first aspect, the present invention is directed to an apparatus for recovering a clock and data which includes a transition detecting circuit and a clock recovery circuit. The transition detecting circuit detects a transition of an input data signal to provide a transition interval of the input data signal. The clock recovery circuit generates a recovered clock based on the input data signal during the transition interval of the input data signal.

In some embodiments, the transition detection circuit may include: a delay circuit configured to delay the input data signal to generate a delayed data signal; and a transition interval decision circuit configured to decide a transition interval of the input data signal based on the delayed data signal.

The delay circuit may include: a first delay circuit configured to generate a first data signal that is delayed by half a clock period with respect to the input data signal; and a second delay circuit configured to generate a second data signal delayed by one clock period with respect to the input data signal. The delay circuit may further include an inversion circuit configured to generate an inverted data signal that is delayed by half the clock period and inverted with respect to the input data signal.

The transition interval decision circuit may include: an increasing transition interval detecting unit configured to receive the delayed data signal and the input data signal to detect an increasing transition interval of the input data signal; and a decreasing transition interval detecting unit configured to receive the delayed data signal and the input data signal to detect a decreasing transition interval of the input data signal. Each of the increasing transition interval and the decreasing transition interval may be one clock period.

In some embodiments, the clock recovery circuit may include: a phase detector configured to detect a phase difference between the recovered clock and the input data signal during the transition interval of the input data signal; a charge pump configured to generate a control voltage that is varied depending on the phase difference; and a voltage-controlled oscillator (VCO) configured to generate the recovered clock in response to the control voltage.

In one embodiment, the phase detector receives a data transition signal including information about the transition interval of the input data signal from the transition detecting circuit and is activated during the transition interval of the input data signal in response to the data transition signal.

The phase detector may include: a first phase detecting unit configured to detect a first phase difference between the recovered clock and a data signal that is delayed by half a clock period with respect to the input data signal; and a second phase detecting unit configured to detect a second phase difference between the recovered clock and an inverted data signal that is delayed by half the clock period and inverted with respect to the input data signal. The first phase detecting unit may be activated during an increasing transition interval of the input data signal, and the second phase detecting unit is activated during a decreasing transition interval of the input data signal.

In some embodiments, the phase detector may further comprise a multiplexer configured to receive the input data signal and the data signal that is delayed by half the clock period with respect to the input data signal, configured to output the input data signal during an initialization process, and configured to output the data signal delayed by half the clock period after the initialization process.

According to another aspect, the present invention is directed to a method of recovering clock and data which includes detecting a data transition of an input data signal, and adjusting a recovered clock based on the input data signal during a data transition interval when the data transition of the input data signal occurs.

Detecting the data transition of the input data signal may include: generating a delayed data signal by delaying the input data signal; and determining the data transition interval based on the delayed data signal.

Generating the delayed data signal may include: generating a first data signal that is delayed by half a clock period with respect to the input data signal; and generating a second data signal that is delayed by one clock period with respect to the input data signal. Generating the delayed data signal may further include generating an inverted data signal that is delayed by half the clock period and inverted with respect to the input data signal.

Determining the data transition interval may include: detecting an increasing transition interval of the input data signal based on the input data signal and the delayed data signal; and detecting a decreasing transition interval of the input data signal based on the input data signal and the delayed data signal. Each of the increasing transition interval and the decreasing transition interval corresponds to one clock period.

Adjusting the recovered clock may include: detecting a phase difference based on the recovered clock and the input data signal during the data transition interval; generating a control voltage that is varied depending on the phase difference; and generating the recovered clock in response to the control voltage. Detecting the phase difference may be performed during the data transition interval.

Detecting the phase difference may include: detecting a first phase difference between the recovered clock and a data signal that is delayed by half the clock period with respect to the input data signal; and detecting a second phase difference between the recovered clock and an inverted data signal that is delayed by half the clock period and inverted with respect to the input data signal. Detecting the first phase difference may be performed during an increasing transition interval of the input data signal, and detecting the second phase difference may be performed during a decreasing transition interval.

Detecting the phase difference may further include detecting an initial phase difference between the recovered clock and the input data signal during an initialization process, and detecting the first phase difference and detecting the second phase difference are performed after the initialization process.

An apparatus and a method for recovering a clock and data according to an example embodiment of the present invention may reduce power consumption since the recovered clock is adjusted during the data transition interval. In addition, an apparatus for recovering a clock and data according to an example embodiment of the present invention may be configured with a phase detection circuit operating at a half speed of the clock.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 is a block diagram illustrating a conventional CDR apparatus.

FIG. 2 is a block diagram illustrating a CDR apparatus according to an example embodiment of the present invention.

FIG. 3 is a block diagram illustrating a delay circuit of a CDR apparatus according to an example embodiment of the present invention.

FIG. 4 is a block diagram illustrating a transition interval decision circuit of a CDR apparatus according to an example embodiment of the present invention.

FIG. 5 is a block diagram illustrating a phase detector of a CDR apparatus according to an example embodiment of the present invention.

FIG. 6 is a timing diagram illustrating an operation of a CDR apparatus according to an example embodiment of the present invention.

FIG. 7 is a waveform diagram illustrating an operation of a CDR apparatus according to an example embodiment of the present invention.

FIG. 8 is a flow chart illustrating a method of recovering a clock and data according to an example embodiment of the present invention.

FIG. 9 is a flow chart illustrating the initialization step in FIG. 8.

FIG. 10 is a flow chart illustrating the transition detection step and the clock adjustment step in FIG. 8.

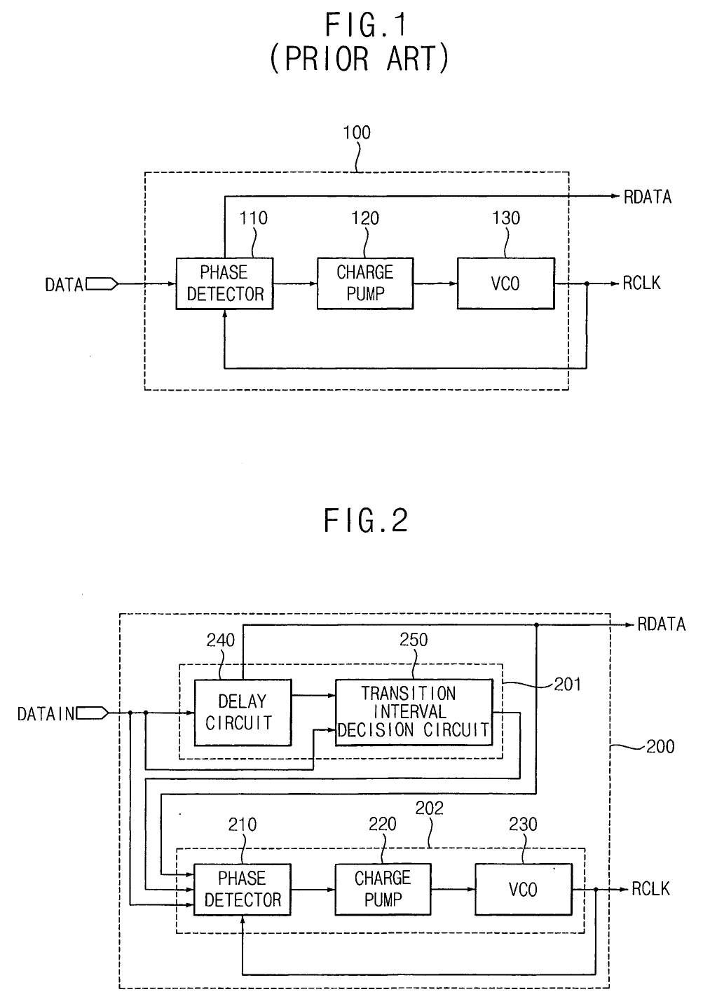

### DESCRIPTION OF THE EMBODIMENTS

Detailed illustrative embodiments of the present invention are disclosed herein. However, specific structural and functional details disclosed herein are merely representative for purposes of describing example embodiments of the present invention. This invention may, however, be embodied in many alternate forms and should not be construed as limited to the embodiments set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 2 is a block diagram illustrating a CDR apparatus for recovering a clock and data, according to an embodiment of the invention.

Referring to FIG. 2, the clock and data recovery (CDR) apparatus 200 includes a transition detecting circuit 201 that detects a transition of an input data signal DATAIN and a clock recovery circuit 202 that generates a recovered clock RCLK during the transition interval of the input data signal DATAIN.

The transition detecting circuit 201 detects an increasing interval (i.e., a rising edge) and a decreasing interval (i.e., a falling edge) of the input data signal DATAIN, and provides a time point of the transition interval to the clock recovery circuit 202. The transition detecting circuit 201 may include a delay circuit 240 for delaying the input data signal DATAIN to generate a delayed data signal, and a transition interval decision circuit 250 for deciding a transition interval by using the input data signal DATAIN and the delayed data signal. That is, the transition detecting circuit 201 may generate a recovered data signal RDATA based on the delayed data signal.

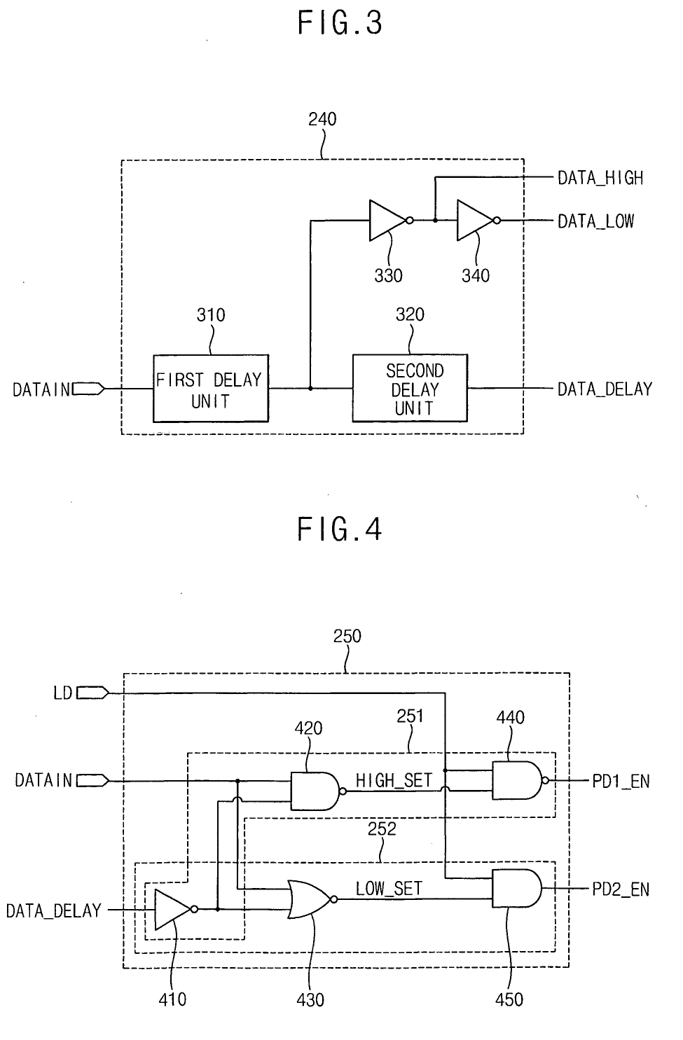

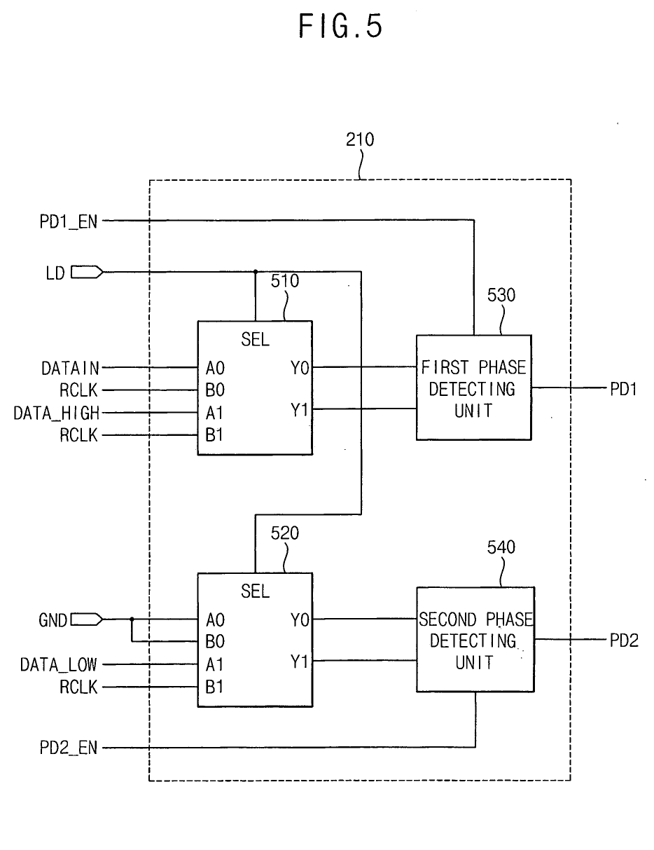

The delay circuit 240 and the transition interval decision circuit 250 will be described with reference to FIGS. 3 and 4.

The clock recovery circuit 202 may include a phase detector 210, a charge pump 220 and a voltage-controlled oscillator VCO 230. The phase detector 210 detects a phase difference between the input data signal DATAIN and the recovered clock RCLK during the transition interval of the input data signal DATAIN. The charge pump 220 provides charges so that a level of a control voltage may be controlled depending on the phase difference. The VCO 230 generates the recovered clock RCLK in response to the control voltage.

The phase detector 210 detects a phase difference between the input data signal DATAIN and the recovered clock RCLK that is fed back from the VCO 230 to provide up/down signals in an initialization process. The up/down signals are provided to the charge pump 220, and the charge pump 220 is charged or discharged according to the up/down signals, thereby increasing or decreasing the control voltage. The VCO 230 generates the recovered clock RCLK having a frequency corresponding to the control voltage. The initialization process is completed when the input data signal DATAIN and the clock RCLK are substantially in phase through above compensation process. After the initialization process, the phase detector 210 detects the phase difference between the delayed data signal compared with the input data signal DATAIN and the recovered clock RCLK to provide the up/down signals. More detailed description of the phase detector 210 will be provided below with reference to FIG. 5.

The VCO 230 generates the recovered clock RCLK depending on the control voltage. In some embodiments, the VCO 230 may provide the recovered clock RCLK and a different clock that is fed back to the phase detector 210. For example, when the VCO 230 is implemented with a delay cell including three inverters that are coupled in series, an output of a middle inverter may be provided as the feedback clock and an output of the last inverter may be provided as the recovered clock RCLK. In this case, the feedback clock and the recovered clock RCLK have the same frequency but phases opposite to each other.

FIG. 3 is a block diagram illustrating a delay circuit of a CDR apparatus according to an example embodiment of the present invention.

Referring to FIG. 3, the delay circuit 240 includes a first delay unit 310 and a second delay unit 320. The first delay unit 310 delays the input data signal DATAIN to generate a data signal delayed by ½ clock period with respect to the input data signal DATAIN. The second delay unit 320 generates a data signal DATA_DELAY delayed by one clock period with respect to the input data signal DATAIN. In some embodiments, the first delay unit 310 and the second delay unit 320 have delay cells of the same configuration as the VCO 230 in FIG. 2. For example, when the VCO 230 is implemented with a delay cell including three inverters, the first delay unit 310 and the second delay unit 320 may be implemented in the same configuration. Therefore, when a clock frequency of the VCO 230 is altered, delay times of the first delay unit 310 and the second delay unit 320 are also altered, such that the first delay unit 310 and the second delay unit 320 may delay the input data signal by ½ clock regardless of the clock change.

The delay circuit 240 may further include a first inverter 330 that inverts an output of the first delay unit 310, and a second inverter 340 that inverts an output of the first inverter 330. When the first delay unit 310 is configured to output a data signal having ½ clock-delay and inverted phase with respect to the input data signal DATAIN, the first inverter 330 is configured to output a data signal DATA_HIGH having ½ clock-delay and the same phase with respect to the input data signal DATAIN. When the first delay unit 310 is configured to output a data signal that is not inverted with respect to the input data signal DATAIN, the first inverter 330 may be replaced with a buffer. The second inverter 340 generates a data signal DATA_LOW having ½ clock-delay and inverted phase with respect to the data signal DATA_HIGH. The output of the first inverter 330, that is, the data signal DATA_HIGH may be used as a recovered data signal. Alternatively, the output of the second inverter 340, that is, the data signal DATA_LOW, may be used as a recovered data signal. When the output of the second inverter 340 is used as a recovered data signal, the recovered data signal has phase opposite to the input data signal DATAIN. Additionally, both outputs of the first inverter 330 and the second inverter 340 may be used as a recovered data signal. In this case, the recovered data signal is used as a differential signal pair.

FIG. 4 is a block diagram illustrating a transition interval decision circuit according to an example embodiment of the present invention.

Referring to FIG. 4, a transition interval decision circuit 250 may include an increasing transition interval detecting unit 251 and a decreasing transition interval detecting unit 252. The increasing transition interval detecting unit 251 detects an increasing transition interval of the input data signal DATAIN based on the data signal DATA_DELAY delayed by 1 clock period and the input data signal DATAIN. The decreasing transition interval detecting unit 252 detects a decreasing transition interval of the input data signal DATAIN based on the 1-clock delayed data signal DATA_DELAY and the input data signal DATAIN.

The increasing transition interval detecting unit 251 activates the phase detector 210 in FIG. 2 during one clock period from a rising edge of the input data signal DATAIN. The increasing transition, interval detecting unit 251 may include an inverter 410, a first NAND gate 420 and a second NAND gate 440. The operation of the increasing transition interval detecting unit 251 is described below.

The first inverter inverts the one clock-delayed data signal DATA_DELAY and outputs the inverted data signal.

The first NAND gate 420 receives the inverted data signal from the first inverter and the input data signal DATAIN. When the input data signal DATAIN transitions from logic ‘low’ to logic ‘high’, the output of the inverter 410 transitions from logic ‘high’ to logic ‘low’ after one clock period from the rising edge of the input data signal DATAIN. That is, during one clock period from the rising edge of the input data signal DATAIN, both inputs of the first NAND gate 420 become logic ‘high’, and the first NAND gate 420 outputs logic ‘low’. When the input data signal DATAIN does not transition and maintains logic ‘low’ or after the input data signal DATAIN transitions from logic ‘high’ to logic ‘low’, the first NAND gate 420 outputs logic ‘high′. Therefore, an increasing transition interval signal HIGH_SET, the output of the first NAND gate 420, may be used as a logic ‘low’ enable signal that is in the state of logic ‘low’ during one clock period from the rising edge of the input data signal DATAIN.

The second NAND gate 440 receives an increasing transition interval signal HIGH_SET and a lock detection signal LD. The lock detection signal LD is logic ‘high’ when the initialization process is completed and the phase of the recovered data signal RDATA is in the lock state. The lock detection signal LD is logic ‘low’ during the initialization process.

When the lock detection signal LD is logic ‘high’ (that is, when the initialization process is completed), and when the increasing transition interval signal HIGH_SET is logic ‘low’, the output signal PD1_EN of the second NAND gate 440 is logic ‘high’, that is, activated. When the lock detection signal LD is logic ‘high’, and when the increasing transition interval signal HIGH_SET is logic ‘high’, the output signal PD1_EN of the second NAND gate 440 is logic ‘low’, that is, deactivated.

When the lock detection signal LD is logic ‘low’, the output signal PD1_EN of the second NAND gate 440 is logic ‘high’, that is, inactivated regardless of a logic level of the increasing transition interval signal HIGH_SET.

The decreasing transition interval detecting unit 252 activates the phase detector 210 in FIG. 2 during one clock period from the falling edge of the input data signal DATAIN. The decreasing transition interval detecting unit 252 may include an inverter 410, a NOR gate 430 and an AND gate 450. The operation of the decreasing transition interval detecting unit 252 may be described as follows.

The inverter 410 inverts the one clock-delayed data signal DATA_DELAY and outputs the inverted data signal.

The NOR gate 430 receives the inverted data signal from the first inverter and the input data signal DATAIN. When the input data signal DATAIN transitions from logic ‘high’ to logic ‘low’, the output of the inverter 410 transitions from logic ‘low’ to logic ‘high’ after one clock period from the falling edge of the input data signal DATAIN. That is, during one clock period from the falling edge of the input data signal DATAIN, both inputs of the NOR gate 430 become logic ‘low’ and the NOR gate 430 outputs logic ‘high′. When the input data signal DATAIN does not transition and maintains logic ‘high’ or after the input data signal DATAIN transitions from logic ‘low’ to logic ‘high’, the NOR gate 430 outputs logic ‘low′. Therefore, a decreasing transition interval signal LOW_SET, the output of the NOR gate 430, may be used as a logic ‘high’ enable signal that is in the state of logic ‘high’ during one clock period from the falling edge of the input data signal DATAIN.

The AND gate 450 receives a decreasing transition interval signal LOW_SET and the lock detection signal LD. The lock detection signal LD is logic ‘high’ when the initialization process is completed and the phase of the recovered data signal RDATA is in the lock state. The lock detection signal LD is logic ‘low’ during the initialization process.

When the lock detection signal LD is logic ‘high’ (that is, when the initialization process is completed), and when the decreasing transition interval signal LOW_SET is logic ‘high’, the output signal PD2_EN of the AND gate is logic ‘high’, that is, activated. When the lock detection signal LD or the decreasing transition interval signal LOW_SET is logic ‘low’, the output signal PD2_EN of the AND gate 450 is logic ‘low’, that is, deactivated.

FIG. 5 is a block diagram illustrating a phase detector 210 of a CDR apparatus according to an example embodiment of the present invention.

The phase detector 210 includes a first phase detecting unit 530 and a second phase detecting unit 540. The first phase detecting unit 530 detects a phase difference between the data signal DATA_HIGH delayed by ½ clock period and the recovered clock RCLK. The second phase detecting unit 540 detects a phase difference between the data signal DATA_LOW inverted and delayed by ½ clock and the recovered clock RCLK. In addition, the phase detector 210 may further include a first multiplexer 510 and a second multiplexer 520 that select a signal provided to the first phase detector 530 and the second phase detector 540, respectively.

During the initialization process, the lock detection signal LD is logic ‘low’, and the input data signal DATAIN alternates between logic ‘high’ and logic ‘low′. The first multiplexer 510 outputs the input data signal DATAIN and the recovered clock RCLK, and the second multiplexer 520 does not output signals. The first phase detector 530 detects a phase difference between the input data signal DATAIN and the recovered clock RCLK to output an up/down signal PD1. The up/down signal PD1 is provided to the charge pump 220 in FIG. 2 to increase or to decrease the control voltage.

When the initialization process is completed, the lock detection signal LD becomes logic ‘high’, and the input data signal DATAIN has some information. Therefore the transition of the input data signal DATAIN has a random characteristic. Because the lock detection signal LD is logic ‘high’, the first multiplexer 510 outputs the data signal DATA_HIGH delayed by ½ clock period and the recovered clock RCLK, and the second multiplexer 520 outputs data signal DATA_LOW inverted and delayed by ½ clock period and the recovered clock RCLK. When the signal PD1_EN is logic ‘high’, that is, during the increasing transition interval, the first phase detecting unit 530 detects a phase difference between the data signal DATA_HIGH delayed by ½ clock period and the recovered clock RCLK to output the up/down signal PD1 depending on the phase difference. When the signal PD2_EN is logic ‘high’, that is, during the decreasing transition interval, the second phase detecting unit 540 detects a phase difference between the data signal DATA_LOW inverted and delayed by ½ clock period and the recovered clock RCLK to output the up/down signal PD2 depending on the phase difference. The up/down signals PD1 and PD2 are provided to the charge pump 220 in FIG. 2 to control the control voltage. The VCO 230 in FIG. 2 adjusts the recovered clock RCLK in response to the control voltage.

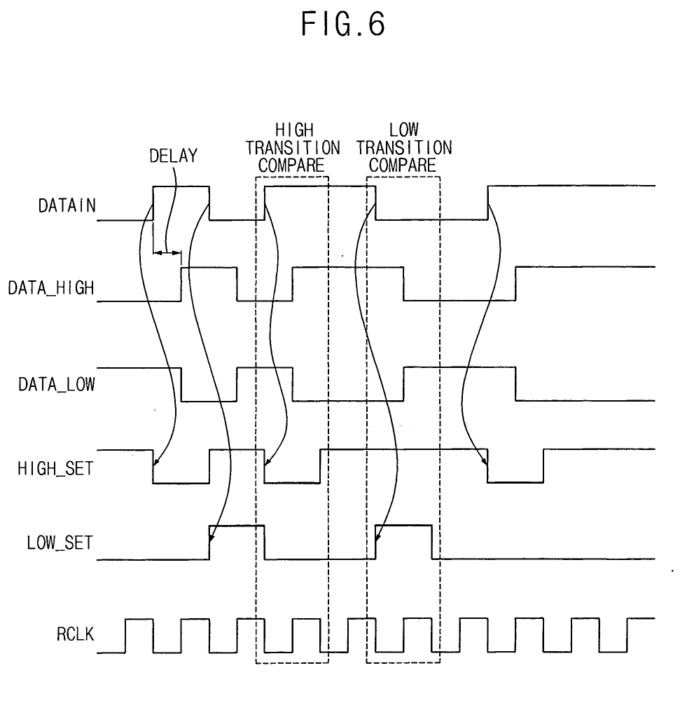

FIG. 6 is a timing diagram illustrating an operation of a CDR apparatus according to an example embodiment of the present invention.

The data signal DATA_HIGH and the data signal DATA_LOW are delayed by ½ clock period with respect to the input data signal DATAIN. The data signal DATA_HIGH is in phase with respect to the input data signal DATAIN and the data signal DATA_LOW is in reverse phase with respect to the input data signal DATAIN.

The increasing transition interval signal HIGH_SET is in the state of logic ‘low’ during one clock period from the rising edge of the input data signal DATAIN, and the decreasing transition interval signal LOW_SET is in the state of logic ‘high’ during one clock period from the falling edge of the input data signal DATAIN. The bolded lines of the increasing transition interval signal HIGH_SET and the decreasing transition interval signal LOW_SET in FIG. 6 denote data transition intervals.

As illustrated in FIG. 6, when the recovered clock RCLK and the input data signal DATAIN are in phase, the data signal DATA_HIGH delayed by ½ clock period and the recovered clock RCLK are in phase during logic ‘low’ of the increasing transition interval signal HIGH_SET, and the data signal DATA_LOW inverted and delayed by ½ clock and the recovered clock RCLK are in phase during logic ‘high’ of the decreasing transition interval signal LOW_SET.

When the increasing transition interval signal HIGH_SET is in the state of logic ‘low’, that is, in the increasing transition interval, the data signal DATA_HIGH delayed by ½ clock period and the recovered clock RCLK are compared to each other. The phase difference between the data signal DATA_HIGH delayed by ½ clock period and the recovered clock RCLK is used for adjusting the recovered clock RCLK.

When the decreasing transition interval signal LOW_SET is in the state of logic ‘high’, that is, in the decreasing transition interval, the data signal DATA_LOW inverted and delayed by ½ clock and the recovered clock RCLK are compared to each other. The phase difference between the data signal DATA_LOW inverted and delayed by ½ clock and the recovered clock RCLK is used for adjusting the recovered clock RCLK.

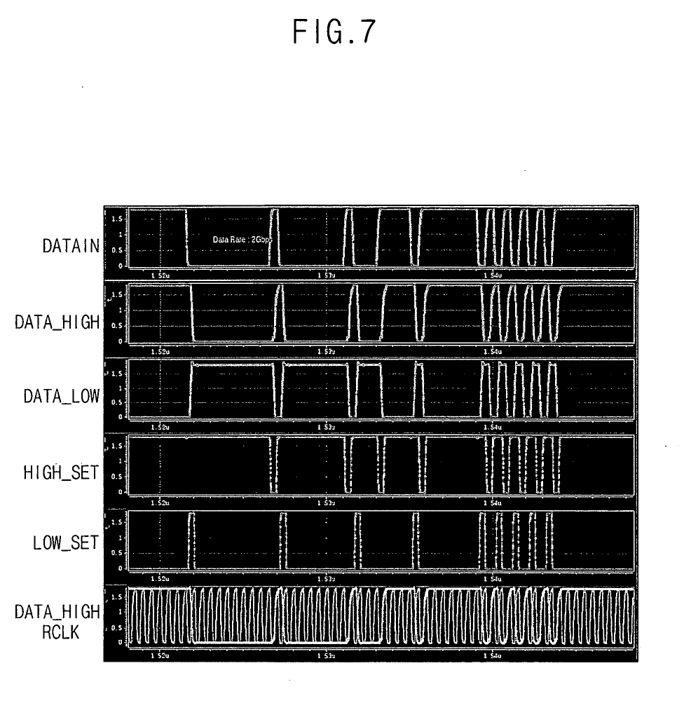

FIG. 7 is a waveform diagram illustrating an operation of a CDR apparatus according to an example embodiment of the present invention.

The data signal DATA_HIGH and the data signal DATA_LOW are delayed by ½ clock period with respect to the input data signal DATAIN. The data signal DATA_HIGH and the data signal DATA_LOW have phases opposite to each other.

The increasing transition interval signal HIGH_SET is in the state of logic ‘low’ during one clock period from the rising edge of the input data signal DATAIN, and the decreasing transition interval signal LOW_SET is in the state of logic ‘high’ during one clock period from the falling edge of the input data signal DATAIN.

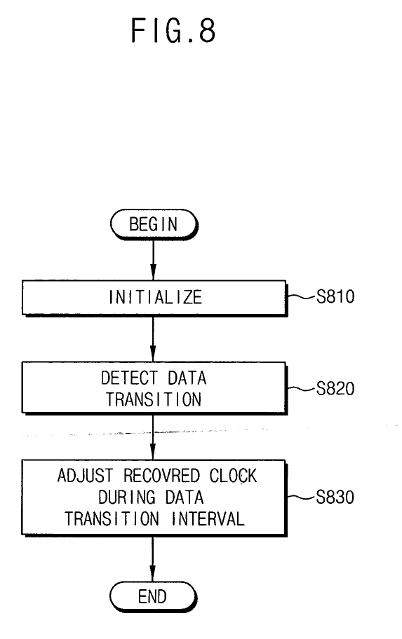

FIG. 8 is a flow chart illustrating a method of recovering a clock and data according to an example embodiment of the present invention.

The method of recovering a clock and data includes initializing a recovered clock (step S810), detecting data transition (step S820) and adjusting the recovered clock during a data transition interval (step S830).

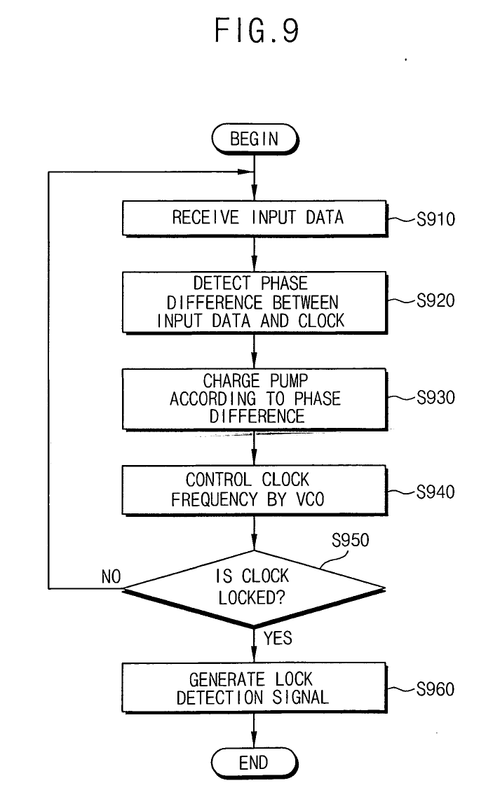

A signal alternating between logic ‘high’ and logic ‘low’ is provided as an input data signal and a clock is initialized based on the input signal in the initialization step S810. The initialization step S810 will be further described with reference to FIG. 9.

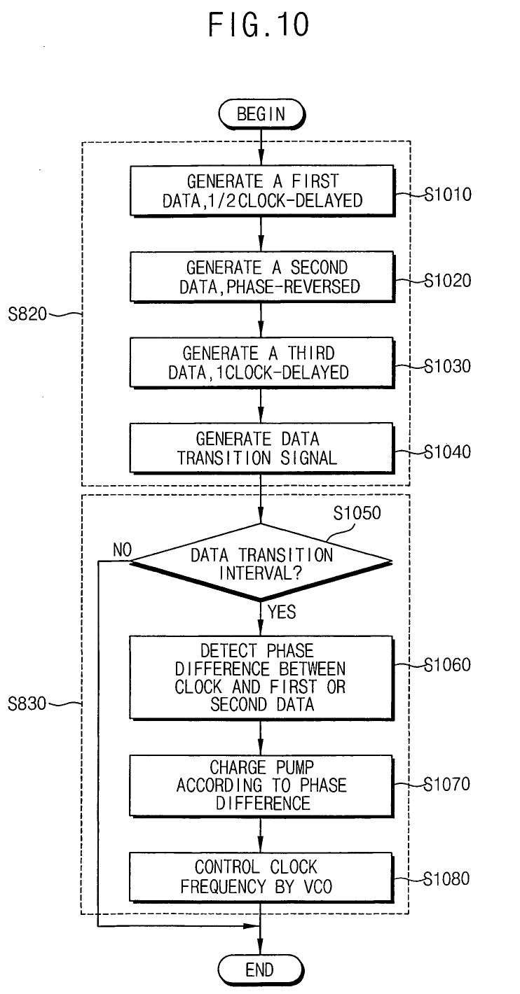

When the initialization is completed, a transition of the input data signal is detected (step S820). When the transition of the input data signal is detected, the recovered clock is adjusted during a date transition interval (step S830). For example, a phase difference is detected by comparing the recovered clock and the data signal delayed by ½ clock period with respect to the input signal to adjust the recovered clock based on the detected phase difference. The transition detection step S820 and the clock adjustment step 830 will be further described with reference to FIG. 10.

FIG. 9 is a flow chart illustrating the initialization step in FIG. 8.

When the CDR apparatus receives an input data signal S910, a phase difference between the input data signal and the recovered clock is detected S920. The input data signal alternates between logic ‘high,’ i.e. ‘1’ and logic ‘low,’ i.e. ‘0’ for the initialization process.

The CDR apparatus decides a level of the control voltage by pumping charges according to the phase difference S930. The CDR apparatus controls clock frequency depending on the control voltage S940. The CDR apparatus decides whether the clock is locked or not S950. When the clock is not locked, the steps S910 to S950 are repeated. In the initial process, the clock and data signal are not in phase, the clock becomes locked by repeatedly performing the steps S910 to S950. When the clock is locked, the CDR apparatus generates a lock detecting signal S960.

FIG. 10 is a flow chart illustrating the transition detection step and the clock adjustment step in FIG. 8.

When the initialization process is completed, the CDR apparatus detects the transition of the input data signal (step S820) to adjust the recovered clock based on the input data signal during the data transition interval (step S830).

Hereinafter, detecting the transition of the input data signal (step S820) is described in detail.

The CDR apparatus generates a first data signal, the data signal delayed by ½ clock period with respect to the input data signal (step S1010), and generates a second data signal, the phase-reversed data signal with respect to the first data signal (step S1020). For example, the first data signal delayed by ½ clock may be in phase with respect to the input data signal. The CDR apparatus generates a third data signal that is delayed by one clock period with respect to the input data signal (step S1030). When the third data signal is generated, the CDR apparatus generates a data transition signal in response to the third data signal. For example, the data transition signal may include an increasing transition interval signal and a decreasing transition interval signal.

When the data transition signal is generated, the recovered clock is adjusted during the data transition interval (step S830).

The CDR apparatus checks whether the input data signal are in the data transition interval based on the data transition signal (step S1050). When the input data signal is in the data transition interval, a phase difference between the first data signal (or the second data signal) and the clock is detected (step S1060). In an example embodiment of the present invention, when the increasing transition interval signal is activated, the phase difference between the first data signal and the clock is detected, and when the decreasing transition interval signal is activated, the phase difference between the second data signal and the clock is detected (step S1060).

The CDR apparatus pumps charges based on the phase difference (step S1070). The level of the control voltage is determined by the pumped charge. The CDR apparatus controls the frequency of the clock using the VCO based on the control voltage (step S1080).

As described above, the clock and data recovery (CDR) apparatus according to an example embodiment of the present invention may reduce power consumption since the recovered clock is adjusted during the data transition interval. In addition, the CDR apparatus according to an example embodiment of the present invention may be configured with a phase detection circuit operating at a half speed of the clock.

While the example embodiments of the present invention and their advantages have been described in detail, it should be understood that various changes, substitutions and alterations may be made herein without departing from the scope of the invention.

What is claimed is:

1. An apparatus for recovering a clock and data, comprising:
a transition detecting circuit configured to detect a transition of an input data signal to provide a transition interval of the input data signal; and
a clock recovery circuit configured to generate a recovered clock based on the input data signal during the transition interval of the input data signal.

2. The apparatus of claim 1, wherein the transition detection circuit comprises:
a delay circuit configured to delay the input data signal to generate a delayed data signal; and
a transition interval decision circuit configured to decide a transition interval of the input data signal based on the delayed data signal.

3. The apparatus of claim 2, wherein the delay circuit comprises:
a first delay circuit configured to generate a first data signal that is delayed by half a clock period with respect to the input data signal; and
a second delay circuit configured to generate a second data signal delayed by one clock period with respect to the input data signal.

4. The apparatus of claim 3, wherein the delay circuit further comprises an inversion circuit configured to generate an inverted data signal that is delayed by half the clock period and inverted with respect to the input data signal.

5. The apparatus of claim 2, wherein the transition interval decision circuit comprises:
an increasing transition interval detecting unit configured to receive the delayed data signal and the input data signal to detect an increasing transition interval of the input data signal; and
a decreasing transition interval detecting unit configured to receive the delayed data signal and the input data signal to detect a decreasing transition interval of the input data signal.

6. The apparatus of claim 5, wherein each of the increasing transition interval and the decreasing transition interval corresponds to one clock period.

7. The apparatus of claim 1, wherein the clock recovery circuit comprises:
a phase detector configured to detect a phase difference between the recovered clock and the input data signal during the transition interval of the input data signal;
a charge pump configured to generate a control voltage that is varied depending on the phase difference; and
a voltage-controlled oscillator (VCO) configured to generate the recovered clock in response to the control voltage.

8. The apparatus of claim 7, wherein the phase detector receives a data transition signal including information about the transition interval of the input data signal from the transition detecting circuit, and is activated during the transition interval of the input data signal in response to the data transition signal.

9. The apparatus of claim 8, wherein the phase detector comprises:
a first phase detecting unit configured to detect a first phase difference between the recovered clock and a data signal that is delayed by half a clock period with respect to the input data signal; and
a second phase detecting unit configured to detect a second phase difference between the recovered clock and an inverted data signal that is delayed by half the clock period and inverted with respect to the input data signal.

10. The apparatus of claim 9, wherein the first phase detecting unit is activated during an increasing transition interval of the input data signal, and the second phase detecting unit is activated during a decreasing transition interval of the input data signal.

11. The apparatus of claim 9, wherein the phase detector further comprises a multiplexer configured to receive the input data signal and the data signal that is delayed by half the clock period with respect to the input data signal, configured to output the input data signal during an initialization process, and configured to output the data signal delayed by half the clock period after the initialization process.

12. A method of recovering clock and data comprising:
detecting a data transition of an input data signal; and
adjusting a recovered clock based on the input data signal during a data transition interval when the data transition of the input data signal occurs.

13. The method of claim 12, wherein detecting the data transition of the input data signal comprises:
generating a delayed data signal by delaying the input data signal; and
determining the data transition interval based on the delayed data signal.

14. The method of claim 13, wherein generating the delayed data signal comprises:
generating a first data signal that is delayed by half a clock period with respect to the input data signal; and
generating a second data signal that is delayed by one clock period with respect to the input data signal.

15. The method of claim 14, wherein generating the delayed data signal further comprises generating an inverted data signal that is delayed by half the clock period and inverted with respect to the input data signal.

16. The method of claim of 13, determining the data transition interval comprises:
detecting an increasing transition interval of the input data signal based on the input data signal and the delayed data signal; and
detecting a decreasing transition interval of the input data signal based on the input data signal and the delayed data signal.

17. The method of claim 16, wherein each of the increasing transition interval and the decreasing transition interval corresponds to one clock period.

18. The method of claim 12, wherein adjusting the recovered clock comprises:
detecting a phase difference based on the recovered clock and the input data signal during the data transition interval;
generating a control voltage that is varied depending on the phase difference; and
generating the recovered clock in response to the control voltage.

19. The method of claim 18, wherein detecting the phase difference is performed during the data transition interval.

20. The method of claim 19, wherein detecting the phase difference comprises:
detecting a first phase difference between the recovered clock and a data signal that is delayed by half the clock period with respect to the input data signal; and
detecting a second phase difference between the recovered clock and an inverted data signal that is delayed by half the clock period and inverted with respect to the input data signal.

21. The method of claim 20, wherein detecting the first phase difference is performed during an increasing transition interval of the input data signal, and wherein detecting the second phase difference is performed during a decreasing transition interval.

22. The method of claim 20, wherein detecting the phase difference further comprises detecting an initial phase difference between the recovered clock and the input data signal during an initialization process, and
wherein detecting the first phase difference and detecting the second phase difference are performed after the initialization process.
